(19) United States
(12) Patent Application Publication
(10) Pub. No.: US 2017/0011909 A1
(43) Pub. Date: Jan. 12, 2017

(54) EMISSIVITY, SURFACE FINISH AND POROSITY CONTROL OF SEMICONDUCTOR REACTOR COMPONENTS

(71) Applicant: ASM IP HOLDING B.V., Almere (NL)

(72) Inventors: Carl Louis White, Phoenix, AZ (US); John Kevin Shugrue, Phoenix, AZ (US)

(73) Assignee: ASM IP HOLDING B.V.

(21) Appl. No.: 14/792,051

(22) Filed: Jul. 6, 2015

(51) Int. Cl. H01L 21/02; C25D 5/34; C23C 16/455

(52) U.S. Cl. CPC H01L 21/02271; C23C 16/45565; C25D 5/34

(57) ABSTRACT

An apparatus and methods are provided related to a surface of a reaction chamber assembly component. The surface may be roughened and/or anodized to provide desirable emissivity and porosity to help reduce burn-in time of a reaction chamber and to help reduce particles within the chamber. The apparatus and methods may be suitable for thin film deposition on semiconductor or other substrates.

### BACKGROUND

Technical Field

The technical field relates to reaction chamber or processing chamber components such as used in the treatment of semiconductor substrates, methods of preparing such components and methods of using such components. Such components and methods may be related to the emissivity, surface finish and porosity of the components.

Background Information

For many semiconductor fabrication processes, a semiconductor substrate or wafer may be heated within a processing chamber. In some instances, the substrate or wafer is seated on a heated susceptor. Coatings may be applied to the semiconductor substrates by various methods including atomic layer deposition (ALD) and chemical vapor deposition (CVD). Such methods may or may not use a showerhead within the processing chamber.

During the use of a reaction or processing chamber, emissivity may change on the processing chamber surfaces as process films are deposited thereon, which occurs as the process film is likewise being deposited on the substrate. This change in emissivity may impact the time required to reach a stable process (burn-in time) in which the film deposition on the substrate is consistent. In addition to unusable wafers which may be processed during burn-in time, production time may also be lost.

Coatings or surface treatments which are applied to reactor or process chamber components for protection and/or desired emissivity can be relatively porous and thus may consume a considerable amount of process chemistry or film deposition before a stable process is achieved. In addition, surface finish of such components may influence the adhesion of deposited films on these components. Poor adhesion of the film over time may cause the film material to crack or separate from the chamber wall or other components, which may lead to an increase in the number of undesired particles within the reaction chamber.

### SUMMARY

In one aspect, an apparatus may comprise an aluminum alloy reaction chamber assembly component having at least one anodized surface layer.

In another aspect, a method may comprise the steps of blasting with blast media a surface of an aluminum alloy reaction chamber assembly component to produce a blasted surface having a surface roughness; and anodizing the blasted surface to form an anodized surface layer.

In another aspect, a method may comprise the steps of providing an aluminum alloy reaction chamber assembly component with an anodized surface layer; depositing a thin film on the anodized surface layer within a reaction chamber; and depositing a thin film on a substrate within the reaction chamber.

### BRIEF DESCRIPTION OF THE SEVERAL VIEWS OF THE DRAWINGS

A sample embodiment is set forth in the following description, is shown in the drawings and is particularly and distinctly pointed out and set forth in the appended claims.

FIG. 1 is a sectional view taken from the side of a sample embodiment of a reactor system.

FIG. 2 is a flow chart showing a sample method.

Similar numbers refer to similar parts throughout the drawings.

### DETAILED DESCRIPTION

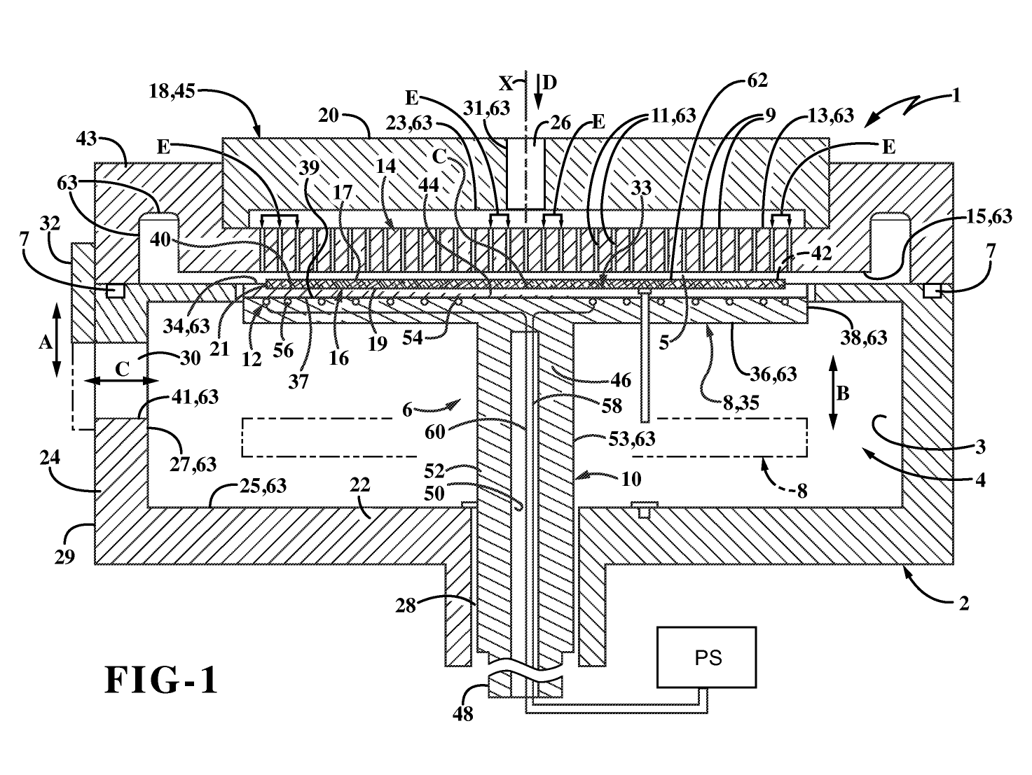

FIG. 1 shows a reactor system, reaction chamber assembly or processing chamber assembly 1 which includes a reaction chamber or processing chamber 2 defining an interior chamber 4 in which may be disposed a substrate support and heating assembly 6 which may comprise a susceptor assembly 8 and a riser shaft 10. Chamber 4 includes a loading region 3 and a processing region 5 directly above and in communication with region 3. Assembly 6 may also be referred to as a substrate support assembly, a substrate heating assembly, a support assembly, a heating assembly or the like. Assembly 6 may include heater 12 in chamber 4 for providing heat to susceptor assembly 8 and riser shaft 10.

A thin film deposition showerhead may comprise a showerhead plate 14 disposed in region 5 of chamber 4 for depositing films such as by chemical vapor deposition or one atomic layer at a time (atomic layer deposition) on a substrate or wafer 16 which may be a semiconductor substrate or wafer (e.g., formed of silicon, gallium arsenide, alumina titanium carbide, etc.). Showerhead plate 14 has an upwardly facing top surface 13 and a downwardly facing bottom surface 15. Surfaces 13 and 15 may be parallel to one another and horizontal or essentially horizontal, or may have other configurations which may be angled relative to horizontal and to one another. In one implementation, surface 17 of wafer 16 is an exposed surface when wafer 16 is in interior chamber 4 of reaction chamber 2 and seated or resting on substrate support assembly 6 as discussed further below. A plurality of showerhead passages 9 are formed in showerhead plate 14 defined by respective inner surfaces 11 which extend from top surface 13 to bottom surface 15 such that passages likewise extend from top surface 13 to bottom surface 15. As known in the art, there may be tens or hundreds or more passages 9 formed in or defined by showerhead plate 14. Passages 9 may be vertical, may have a circular cross section and may have, for example, a diameter on the order of about 1.0 millimeter although this may vary. Passages 9 extend through showerhead plate 14 to upper or processing region 5. Substrate 16 is typically thin and flat and may be disc shaped. Substrate 16 may have a flat circular top surface 17, a flat circular bottom surface 19 and a circular outer perimeter 21 extending from top surface 17 to bottom surface 19. Surfaces 17 and 19 may be parallel to one another and horizontal or essentially horizontal, and may be parallel to surfaces 13 and 15 of showerhead plate 14.

Reaction chamber 2 may include a top wall 18, a bottom wall 22 having an inner top surface 25, and a sidewall 24 having an inner surface 27 and an outer surface 29. Top wall 18 may include an annular outer section 43 of the showerhead and an inner section or plate 45 of the showerhead which may be a flat horizontal wall which may be circular as viewed from above. Plate 45 may be referred to as a gas channel plate and may be seated within a recess or opening defined by outer section 43 such that gas channel plate 45 is directly above and adjacent showerhead plate 14, which may be secured to an inner perimeter of outer section 43. Top wall 18 may have an outer top surface 20 and an inner bottom surface 23 which may serve as top and bottom surfaces of plate 45. Bottom surface 23 of plate 45 may be horizontal or essentially horizontal, may be adjacent and parallel to top surface 13 of showerhead plate 14, and may be parallel to bottom surface 15 of showerhead plate 14 although bottom surface 23 and surface 13 and 15 may taper or angle in various ways as well. Although the shape may vary, top and bottom walls 18 and 22 are typically, generally flat walls which are generally circular as viewed from above. Similarly, although the shape of sidewall 24 may vary, it is typically generally cylindrical. Outer section 43 of the showerhead may be seated atop sidewall 24 so as to form an airtight or gastight seal between section 43 and sidewall 24. For instance, the showerhead may be removably connected to sidewall 24 with an annular seal 7 between and engaging section 43 and sidewall 24 to provide this gastight seal.

A gas supply port 26 defined by an inner surface 31 of plate 45 is formed in top wall 18/plate 45 extending from top surface 20 to bottom surface 23 and in fluid communication with region 5 of chamber 4 and an external gas supply or supplies to provide a desired gas or gases from outside chamber 2 into interior chamber 4. A riser shaft receiving passage 28 is defined in bottom wall 22 for receiving therein riser shaft 10. A substrate or wafer insertion and removal port 30 is defined in sidewall 24 by an inner surface 41 extending from inner surface 27 to outer surface 29. Port 30 allows for the insertion therethrough of substrate 16 into loading region 3 of chamber 4 and removal of substrate 16 from loading region 3 when a valve or door 32 is in the open position as shown in solid lines in FIG. 1. Valve or door 32 is movable (Arrow A) between the open position and a closed position shown in dashed lines. Valve 32 in the closed position seals chamber 4 to prevent gas from moving into or exiting chamber 4 through port 30.

Susceptor assembly 8 is typically a generally flat, horizontal plate and usually has a disc shaped configuration. Susceptor assembly 8 may include a susceptor 33 and a support plate or heater plate 35 which may be rigidly secured to susceptor 33 with susceptor 33 atop plate 35. Each of susceptor 8 and plate 35 is typically a flat, horizontal plate and usually has a disc shaped configuration. Susceptor assembly 8 may have a circular upwardly facing top surface 34 which also serves as a top surface of susceptor 33, a circular downwardly facing bottom surface 36 which also serves as a bottom surface of plate 35, and an outer perimeter 38 or diameter which extends from top surface 34 to bottom surface 36 and may also serve respectively as outer perimeters of susceptor 33 and plate 35. Outer perimeter 38 is typically circular or cylindrical. Susceptor 33 may have a circular downwardly facing bottom surface 37, and plate 35 may have a circular upwardly facing top surface 39 which abuts and is rigidly secured to bottom surface 37. Susceptor assembly 8/susceptor 33 has an upwardly facing flat horizontal substrate support surface 40 which in the sample embodiment is recessed downwardly a small distance from top surface 34 whereby surface 34 may be a flat annular circular surface. Surfaces 34, 36, 37 and 40, and top surface 17 of wafer 16 when wafer 16 is seated on surface 40, may be parallel or essentially parallel to top and bottom surfaces 13 and 15 of showerhead plate 14. Upwardly facing surfaces 34, 40 and 17 are adjacent bottom surface 15 when support assembly 6 is in the raised position and distal bottom surface 15 when support assembly 6 is in the lowered position. Susceptor assembly 8/susceptor 33 may define a substrate receiving space 42 which extends upwardly from support surface 40 a short distance and has the shape and dimensions of substrate or wafer 16, whereby top surface 17, bottom surface 19 and outer perimeter 21 may also respectively represent the top, bottom and outer perimeter of space 42. Susceptor assembly 8 has a central region 44 which extends radially outwardly from a center C of susceptor assembly 8 which lies on a typically vertical longitudinal axis X about which support assembly 6 is rotatable. Susceptor 33 and plate 35 may be formed of metal, graphite or another suitable material.

Riser shaft 10 has a first or top end 46 and an opposed second or bottom end 48. Riser shaft 10 is typically vertically elongated and defines a vertical or vertically elongated riser shaft passage 50 which extends from first end 46 to second end 48 and through which axis X passes. More particularly, riser shaft 10 has a sidewall 52 having an outer perimeter or surface 53 which faces away from passage 50. Surface 53 extends from first end 46 to second end 48. First end 46 is in interior chamber 4 while the second end 48 is outside chamber 4. Susceptor assembly 8 is secured to riser shaft 10 adjacent top end 46 and extends radially outwardly therefrom. Outer perimeter or diameter 38 of susceptor assembly 8 is substantially larger than outer perimeter or diameter 53 of shaft 10. Riser shaft 10/sidewall 52 may be formed of metal, graphite or another suitable material.

Susceptor heater 12 may have a first or inner heating element shown here as a heating coil 54 and a second or outer heating element shown here as a heating coil 56. Heating elements 54 and 56 may extend along and be carried by susceptor assembly 8 and may be embedded in susceptor assembly 8, such as along the interface between susceptor 33 and plate 35 adjacent bottom surface 37 and top surface 39. Although shown here as heating coils, other configurations are contemplated. Wires 58 are connected to first coil 54 and a power source and controller PS to provide electrical communication between coil 54 and power source/controller PS. Wires 60 are likewise connected to second coil 56 and power supply and control PS to provide electrical communication between coil 54 and power source/controller PS. The power supply for the coils may be different and each of the coils may be independently controlled. Each of coils 54 and 56 may have a spiral shape which spirals outwardly away from axis X such that each coil may be a planar heating coil.

Various reaction or processing chamber assembly components—such as riser shaft 10/sidewall 52, showerhead plate 14, top wall 18, bottom wall 22, sidewall 24, riser shaft 10, and susceptor assembly 8 including susceptor 33 and plate 35—may be formed of an anodizable metal or metal alloy such as an aluminum alloy. For example, one aluminum alloy which may be used is Al 5083 or others in the 5000 series. Another such alloy is Al 6061 or others in the 6000 series although some of these alloys may be less desirable in some circumstances because of a higher copper content. It may be desired that the aluminum alloy have a copper content by weight of no more than 0.5% or 0.25%. There are innumerable other suitable aluminum alloy possibilities, wherein the alloy is primarily aluminum and may be, for example, at least 80%, 85% or 90% aluminum by weight.

Various reaction or processing chamber assembly component surfaces of such components may be finished in a manner that substantially reduces or essentially eliminates the burn-in time which is often required in the processing of substrates/wafers 16, as discussed in the Background section herein, and/or which controls porosity to a level which helps reduce particles which might otherwise shed into the gas stream inside the chamber and land on the wafer surface. These component surfaces may include inner surfaces which bound or define interior chamber 4 (including regions 3 and 5 thereof), outer surfaces which are inside or within interior chamber 4, and passage-defining surfaces which communicate with these inner surfaces or outer surfaces and define passages or ports which are in fluid communication with chamber 4. More particularly and for instance, these component surfaces may include bottom surface 23 of top wall 18/plate 45, top surface 25 of bottom wall 22 and inner surface 27 of sidewall 24, which are inner surfaces which bound or define interior chamber 4; top and bottom surfaces 13 and 15 of showerhead plate 14, top, bottom and outer surfaces 34, 36 and 38 of susceptor assembly 8 and outer surface 53 of riser shaft 10, which are outer surfaces within interior chamber 4; and inner surface 31, inner surfaces 11 and inner surface 41, which are passage-defining surfaces which communicate with these inner surfaces or outer surfaces and define passages or ports which are in fluid communication with chamber 4.

These chamber assembly component surfaces may be defined by an anodized surface layer 63 of the various above-noted chamber assembly components which are formed of an anodizable metal or metal alloy. The anodized surface layer may have an anodized surface layer thickness in a range of 3 to 15 microns or micrometers (μm) or within any range of any whole number of microns from 3 to 15, e.g., 3 to 12 μm, 5 to 15 μm, 5 to 12 μm, 5 to 10 μm, 7 to 12 μm, 7 to 10 μm and so forth. These component surfaces, which may or may not be defined by the corresponding anodized surface layers, may have a surface roughness average (Ra) which may fall within a range of 0.8 to 6.3 μm or any numbers within this range, and may be within a range of 1.0 or 2.0 to 4.25 or 4.50 μm. One sample having an Ra of 3.75 to 4.25 μm was found to have desirable qualities. The roughness average may be measured by a suitable surface profilometer. These chamber assembly component surfaces may be referred to in the art as wetted surfaces, which are the surfaces which are exposed to a gas or gases within interior chamber 4 and processing region 5.

In addition, the emissivity of a given anodized surface layer 63 may be, for example, at least 0.50, 0.55, 0.60, 0.65, 0.70, 0.75, 0.80 or 0.85 or fall within a range such as noted below. This anodized surface layer emissivity of the given anodized surface layer 63 may match, essentially match or be within a given tolerance of a deposition film emissivity of the coating or deposition layer or film 62 which is applied to top surface 17 of wafer or substrate 16. For instance, the emissivity of the given anodized surface layer 63 may be within 0.05, 0.10, 0.15, 0.20 or 0.25 of the emissivity of layer or film 62 above or below, that is, ±0.05, ±0.10, ±0.15, ±0.20 or ±0.25 of the emissivity of layer or film 62. One frequently used coating applied to top surface 17 which may form layer 62 is titanium carbide (TiC), which has a relatively high emissivity of about 0.85. Thus, the emissivity of the anodized surface layer when deposition layer 62 is formed of TiC may be on the order of about 0.60, 0.65, 0.70, 0.75, 0.80, 0.85, 0.90, 0.95 or above (approaching 1.0) or in a range defined between any two of these numbers. Other relevant coatings which may be applied to top surface 17 may include a diamond-like carbon coating, an yttria coating or an alumina titanate coating.

Although the emissivity of any of the various noted anodized surface layers 63 may be desirable, it is particularly relevant to the anodized surface layer 63 defining top and bottom surfaces 13 and 15 of showerhead plate 14 inasmuch as the emissivity of these surfaces helps control the temperature of showerhead plate 14 during the deposition process and because bottom surface 15 of showerhead plate 14 faces and is closely adjacent top surface 17 of substrate 16 whereby heat emitted from bottom surface 15 to top surface 17 may affect the temperature of top surface 17 during the deposition process. The various other reaction chamber assembly component surfaces may or may not be defined by an anodized surface layer 63. In various cases, it may be desired that anodized surface layer 63 is not used on certain reaction chamber assembly components to define the corresponding component surfaces, especially those other than the top and bottom surfaces 13 and 15 of showerhead plate 14, whereby these certain component surfaces are roughened and cleaned as discussed further below, but not anodized to form an anodized surface layer thereon. For instance, these certain component surfaces which may be roughened and cleaned, but not anodized may include bottom surface 23 of top wall 18/plate 45, top surface 25 of bottom wall 22, inner surface 27 of sidewall 24, top, bottom and outer surfaces 34, 36 and 38 of susceptor assembly 8, outer surface 53 of riser shaft 10, inner surface 31 defining gas port and inner surface 41 defining insertion/removal port 30.

In operation, coils 54 and 56 may be heated and controlled independently or together by controller PS as desired to provide heat to substrate or wafer 16 by conduction. Coils 54 and 56 primarily provide resistance heat which is transferred by conduction to susceptor assembly 8 (susceptor 33 and plate 35). Heat from susceptor 33, which originated from coils 54 and 56, is in turn transferred by conduction to substrate 16. Thus, susceptor assembly 8 and wafer/substrate 16 may be heated to and maintained at a temperature in various ranges, for instance, within a temperature range of about 50° C. to 800° C. or more.

As known in the art, susceptor assembly 8 and riser shaft 10 are movable up and down (which may be linear vertical movement parallel to axis X) as illustrated at Arrow B between a raised or processing position shown in solid lines and a lowered or loading position shown in dashed lines. This allows for the raising and lowering of substrate 16 and the insertion and removal of substrate 16 as illustrated at Arrow C when valve 32 is in the open position. Thus, riser shaft 10 and susceptor assembly 8 are moved to the lowered position so that susceptor assembly 8 is in loading region 3 and wafer 16 is inserted through opening 30 when valve 32 is open in order to place wafer 16 on top of susceptor assembly 8 atop support surface 40 within space 42. Valve 32 may then be shut and susceptor assembly 8 and shaft 10 lifted back to the raised position with substrate 16 on surface 40 for processing in region 5. The heater assembly 6 is controlled by controller PS to control or adjust the heating and temperature of susceptor assembly 8 and substrate 16 as noted above, whereby controlling such heating and temperature may occur automatically during the film deposition process. With the susceptor assembly and substrate in the raised position and while susceptor assembly 6 is operated to maintain the temperature such as noted above (including while heater assembly 6 may rotate about axis X in some instances), thin film deposition may take place via insertion of a suitable gas (or gases) via port 26 (Arrow D) and showerhead plate 14 passages 9 (Arrows E) in order to deposit thin film 62 on the top exposed surface 17 of substrate 16, such as one atomic layer at a time as generally known in the art. The gas may be heated prior to entering chamber 4 and processing region 5 to a temperature as close as possible to the desired processing temperature of susceptor assembly 8 and substrate 16 to help maintain the substantial uniformity of temperature throughout substrate 16 during processing. Although reactor system 1 is shown using thin film deposition showerhead plate 14 to apply a thin film on substrate 16, other types of reactors may be used for this purpose, such as a cross-flow reactor system, which may also be represented by system 1. One example of such a cross-flow reactor system is the Pulsar® reaction chamber manufactured by ASM America, Inc.

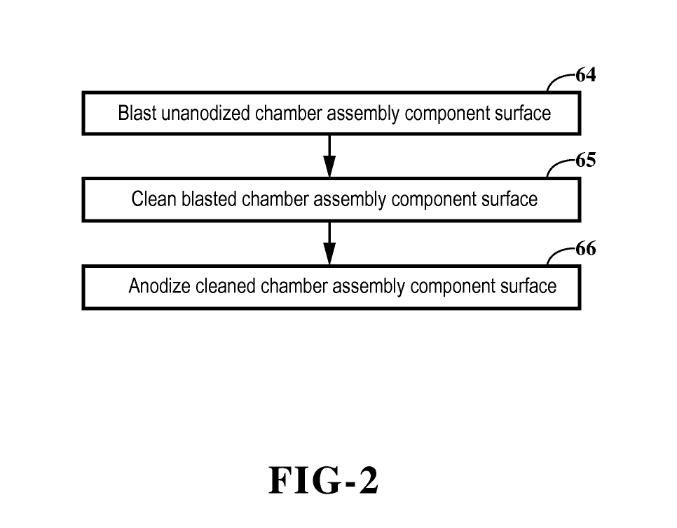

With reference to the flow chart of FIG. 2, a description is now provided of one or more methods of forming one or more of the above-noted chamber assembly components which are formed of an anodizable metal or metal alloy to provide the above-noted chamber assembly component surfaces defined by the anodized surface layers. In short, such a method may include blasting an unanodized chamber assembly component surface to produce a blasted chamber assembly component surface (block 64), cleaning the blasted chamber assembly component surface to produce a cleaned chamber assembly component surface (block 65), and anodizing the cleaned chamber assembly component surface to produce an anodized chamber assembly component surface defined by the anodized surface layer 63 of the given component (block 65). This anodized surface is thus an exposed surface which is initially exposed to any gas or gases within interior chamber 4, that is, exposed to such a gas or gases before film deposition may create a film or coating on the anodized surface which covers the anodized surface to the degree that the anodized surface is no longer so exposed.

More particularly, as indicated at block 64, the unanodized surfaces may be blasted with suitable blast media to provide a desired surface roughness to the surface. In particular, this blasting or treatment may result in a surface roughness average in a range of about 0.4 to 6.3 μm or any numbers within this range, and may be within a range of 0.8 or 2.0 to 4.25 or 4.50 μm. One sample having an Ra of 3.75 to 4.25 μm was found to have desirable qualities. The roughness average may be measured by a suitable surface profilometer. (While other methods such as laser ablation may be used to provide the desired surface roughness, such methods are typically substantially more complicated and expensive.) While various types of blast media may be used, two suitable possibilities which may serve as blast media are alumina grit or particles and zirconia grit or particles.

The roughened surface may then require that the surface be cleaned (block 65) because very fine particles of the blast medium or particles derived from the surface during the blasting may cling to the roughened surface and thus need to be removed, and because of a need for preparing the given surface for anodizing the given surface. The cleaning procedure may include various steps suitable to prepare the surface for anodizing, and it should be understood that the cleaning process may be done in a variety of ways which are suitable in the present context.

By way of example, the cleaning procedure may include immersing or soaking a given chamber assembly component in heated Oakite 61B (e.g., heated to 160 to 190° F.) or equivalent solution for 15 minutes such that all of the blasted chamber assembly component surfaces of the given component are submerged in/contacted by the solution. After removing the component from this solution, the component surfaces may be rinsed and power flushed with deionized (DI) water. The rinsed and flushed component may then be immersed in an acid etch solution (e.g., HNO3/HF/DI water) for 10-15 seconds such that all of the blasted chamber assembly component surfaces of the given component are submerged in/contacted by the acid etch solution, then again rinsed and power flushed with DI water. The rinsed/flushed component may then be immersed in a nitric acid desmut solution (with all relevant surfaces submerged in/in contact with the desmut solution) for one minute to provide desmutting of the component surfaces. The component may then be removed from the desmut solution and again rinsed and power flushed with DI water. The component may then be immersed in an ambient final DI water rinse for 5 minutes, removed therefrom and immersed in a bath in an ultrasonic tank to be ultrasonically cleaned in the bath for one minute. After removal from the ultrasonic tank bath, the component may then be immersed in cleanroom heated DI water for one minute. After removing the component from the heated DI water, it may be blow dried with nitrogen or a clean inert gas such as argon and subsequently put in a suitable oven to bake/dry, for instance, at about 250° F. for about one hour, which may be, for example, in a nitrogen environment.

Once the cleaning procedure is complete, the cleaned surface may be anodized to form the given anodized surface layer 63 of the given chamber assembly component (block 66). The anodization process may take place with the given chamber assembly component disposed in an acid bath or solution which may contain one or more acids. This anodization process is carefully controlled to obtain the desired anodized surface layer thickness noted above. This process results in the desired surface finish, emissivity and relatively low porosity which are beneficial in the operation of the reaction or process chamber so as to substantially reduce or essentially eliminate the burn-in time as discussed above. In addition, the blasting process provides a desirable roughness to the wetted surfaces to promote adhesion of undesirable reactions and film deposition to prevent additional particles within interior chamber 4 which may shed into the gas stream and land on the wafer surface, primarily on its exposed top surface. It is noted that inner surfaces 11 which define showerhead holes 9 may be simply drilled and not blasted to roughen them in the manner that other chamber assembly component surfaces may be roughened, although surfaces 11 may be anodized as otherwise noted herein. In the foregoing description, certain terms have been used for brevity, clearness, and understanding. No unnecessary limitations are to be implied therefrom beyond the requirement of the prior art because such terms are used for descriptive purposes and are intended to be broadly construed. Moreover, the description and illustration of the sample embodiments are examples and not limited to the exact details shown or described.

1. An apparatus comprising:
an aluminum alloy reaction chamber assembly component having at least one anodized surface layer.

2. The apparatus of claim 1 wherein the anodized surface layer has a thickness in a range of 3-15 μm.

3. The apparatus of claim 2 wherein the anodized surface layer has a surface roughness average of 0.4-6.3 μm.

4. The apparatus of claim 3 wherein the anodized surface layer has an emissivity of at least 0.50.

5. The apparatus of claim 1 wherein the anodized surface layer has an emissivity of at least 0.50.

6. The apparatus of claim 1 wherein the anodized surface layer has a surface roughness average of 0.4-6.3 μm.

7. The apparatus of claim 1 wherein the component is a showerhead.

8. The apparatus of claim 7 wherein the at least one anodized surface layer defines a downwardly facing surface of the showerhead.

9. The apparatus of claim 8 wherein the at least one anodized surface layer defines an upwardly facing surface of the showerhead.

10. The apparatus of claim 7 wherein the at least one anodized surface layer defines an upwardly facing surface of the showerhead.

11. The apparatus of claim 7 further comprising a substrate support assembly having a substrate support surface adapted to support thereon a substrate; wherein the showerhead has a surface which is essentially parallel to the substrate support surface; and the at least one anodized surface layer defines the surface of the showerhead.

12. The apparatus of claim 7 wherein the showerhead comprises a showerhead plate; and the at least one anodized surface layer defines a surface of the showerhead plate.

13. The apparatus of claim 12 further comprising a reaction chamber in which the showerhead plate is disposed.

14. The apparatus of claim 13 in combination with a substrate which is in the reaction chamber and has an exposed surface; wherein the surface of the showerhead plate faces the exposed surface.

15. The apparatus of claim 13 in combination with a substrate which is in the reaction chamber and has a surface on which is a thin film having a thin film emissivity; and wherein the at least one anodized surface layer which defines the surface of the showerhead plate has an anodized surface layer emissivity within±0.25 of the thin film emissivity.

16. A method comprising the steps of:
blasting with blast media a surface of an aluminum alloy reaction chamber assembly component to produce a blasted surface having a surface roughness; and
anodizing the blasted surface to form an anodized surface layer.

17. The method of claim 16 further comprising the step of cleaning the surface after the step of blasting and before the step of anodizing.

18. The method of claim 16 wherein the anodized surface layer has a thickness in a range of 3-15 μm and a surface roughness in a range of 0.4-6.3 μm.

19. The method of claim 18 wherein the anodized surface layer has an emissivity of at least 0.50.

20. A method comprising the steps of:
providing an aluminum alloy reaction chamber assembly component with an anodized surface layer;
depositing a thin film on the anodized surface layer within a reaction chamber; and
depositing a thin film on a substrate within the reaction chamber.
